(19) United States
(12) Patent Application Publication
(10) Pub. No.: US 2025/0264717 A1
(43) Pub. Date: Aug. 21, 2025

(54) LASER SYSTEM AND ELECTRONIC DEVICE MANUFACTURING METHOD

(71) Applicant: Gigaphoton Inc., Tochigi (JP)

(72) Inventor: Takahito KUMAZAKI, Oyama-shi (JP)

(73) Assignee: Gigaphoton Inc., Tochigi (JP)

(21) Appl. No.: 19/012,476

(22) Filed: Jan. 7, 2025

(30) Foreign Application Priority Data
Feb. 19, 2024 (JP) 2024-023270

(51) Int. Cl. G02B 26/12; G03F 7/00

(52) U.S. Cl. CPC G02B 26/123; G02B 26/124; G03F 7/70025; G03F 7/70041; G03F 7/7005; G03F 7/7055

(57) ABSTRACT

A laser system includes a first pulse laser apparatus configured to output a first pulse laser beam in a predetermined cycle, a second pulse laser apparatus configured to output a second pulse laser beam in the predetermined cycle, a first polygon mirror configured to reflect the first pulse laser beam and the second pulse laser beam, and a processor configured to control the first pulse laser apparatus, the second pulse laser apparatus, and the first polygon mirror such that the first pulse laser beam and the second pulse laser beam are output with a shift of ½ of the predetermined cycle between them and optical paths of the first pulse laser beam and the second pulse laser beam reflected by the first polygon mirror are oriented in a first direction and at least partially overlapped.

### CROSS-REFERENCE TO RELATED APPLICATIONS

The present application claims the benefit of Japanese Patent Application No. 2024-023270, filed on Feb. 19, 2024, the entire contents of which are hereby incorporated by reference.

### BACKGROUND

### 1. Technical Field

The present disclosure relates to a laser system and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: U.S. Patent Application Publication No. 2023004091
Patent Document 2: Chinese Utility Model No. 219143208
Patent Document 3: U.S. Pat. No. 5,387,211

### SUMMARY

A laser system according to one aspect of the present disclosure may include a first pulse laser apparatus, a second pulse laser apparatus, a first polygon mirror, and a processor. The first pulse laser apparatus may be configured to output a first pulse laser beam in a predetermined cycle. The second pulse laser apparatus may be configured to output a second pulse laser beam in the predetermined cycle. The first polygon mirror may be configured to reflect the first pulse laser beam and the second pulse laser beam. The processor may be configured to control the first pulse laser apparatus, the second pulse laser apparatus, and the first polygon mirror such that the first pulse laser beam and the second pulse laser beam are output with a shift of ½ of the predetermined cycle between the first pulse laser beam and the second pulse laser beam and optical paths of the first pulse laser beam and the second pulse laser beam reflected by the first polygon mirror are oriented in a first direction and at least partially overlapped.

Further, an electronic device manufacturing method according to one aspect of the present disclosure may include outputting a first pulse laser beam and a second pulse laser beam generated by a laser system to an exposure apparatus, and exposing a photosensitive substrate to the first pulse laser beam and the second pulse laser beam within the exposure apparatus to manufacture an electronic device. The laser system may include a first pulse laser apparatus configured to output the first pulse laser beam in a predetermined cycle, a second pulse laser apparatus configured to output the second pulse laser beam in the predetermined cycle, a first polygon mirror configured to reflect the first pulse laser beam and the second pulse laser beam, and a processor configured to control the first pulse laser apparatus, the second pulse laser apparatus, and the first polygon mirror such that the first pulse laser beam and the second pulse laser beam are output with a shift of ½ of the predetermined cycle between the first pulse laser beam and the second pulse laser beam and optical paths of the first pulse laser beam and the second pulse laser beam reflected by the first polygon mirror are oriented in a first direction and at least partially overlapped.

### BRIEF DESCRIPTION OF THE DRAWINGS

Some embodiments of the present disclosure will be described below, by way of example only, with reference to the accompanying drawings.

FIG. 1 is a schematic diagram illustrating a schematic configuration example of an entire electronic device manufacturing apparatus.

FIG. 2 is a schematic diagram illustrating a schematic configuration example of an entire laser system of a comparative example.

FIG. 3 is a schematic diagram illustrating a schematic configuration example of a pulse laser apparatus included in the laser system of the comparative example.

FIG. 4 is a timing chart illustrating a relation between an output timing of a first pulse laser beam and an output timing of a second pulse laser beam.

FIG. 5 is a timing chart illustrating an output timing of pulse coupled light obtained by combining the first pulse laser beam and the second pulse laser beam.

FIG. 6 is a schematic diagram illustrating a schematic configuration example of a laser system of Embodiment 1.

FIG. 7 is a schematic view illustrating a schematic configuration example of a beam steering device.

FIG. 8 is a schematic diagram illustrating a schematic configuration example of a beam measuring instrument.

FIG. 9 is a schematic diagram illustrating a schematic configuration example of a laser system in a modification of Embodiment 1.

FIG. 10 is a schematic diagram illustrating a schematic configuration example of a laser system of Embodiment 2.

FIG. 11 is a timing chart illustrating a relation among output timings of first to fourth pulse laser beams.

FIG. 12 is a timing chart illustrating a relation between output timings of pulse coupled light obtained by combining the first pulse laser beam and the second pulse laser beam and pulse coupled light obtained by combining the third pulse laser beam and the fourth pulse laser beam.

FIG. 13 is a timing chart illustrating an output timing of pulse coupled light obtained by combining the first to fourth pulse laser beams.

FIG. 14 is a schematic diagram illustrating a schematic configuration example of a laser system in a modification of Embodiment 2.

### DESCRIPTION OF EMBODIMENTS

1. Description of Electronic Device Manufacturing Apparatus Used in Electronic Device Exposure Process
2. Description of Laser System of Comparative Example
   2.1 Configuration
   2.2 Operation
   2.3 Problem
3. Description of Laser System of Embodiment 1
   3.1 Configuration
   3.2 Operation
   3.3 Effect and Advantage
   3.4 Modification
4. Description of Laser System of Embodiment 2
   4.1 Configuration
   4.2 Operation
   4.3 Effect and Advantage
   4.4 Modification

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Description of Electronic Device Manufacturing Apparatus Used in Electronic Device Exposure Process

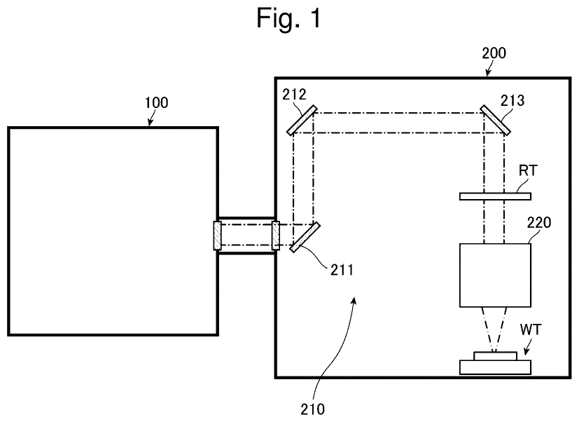

FIG. 1 is a schematic diagram illustrating a schematic configuration example of an entire electronic device manufacturing apparatus used in an electronic device exposure process. As illustrated in FIG. 1, the manufacturing apparatus used in the exposure process includes a laser system 100 and an exposure apparatus 200. The exposure apparatus 200 includes an illumination optical system 210 including a plurality of mirrors 211, 212, and 213 and a projection optical system 220. The illumination optical system 210 illuminates a reticle pattern of a reticle stage RT with a laser beam from the laser system 100. The projection optical system 220 performs reduced projection of a laser beam transmitted through a reticle, and forms an image on an unillustrated workpiece disposed on a workpiece table WT. The workpiece is a photosensitive substrate such as a semiconductor wafer on which photoresist is applied. The exposure apparatus 200 synchronously translates the reticle stage RT and the workpiece table WT to expose the workpiece to a laser beam reflecting the reticle pattern. By transferring a device pattern onto the semiconductor wafer by the exposure process as described above, a semiconductor device that is an electronic device can be manufactured.

### 2. Description of Laser System of Comparative Example

### 2.1 Configuration

A laser system of a comparative example will be described. The comparative example of the present disclosure is an example recognized by the applicant as known only by the applicant, and is not a publicly known example admitted by the applicant.

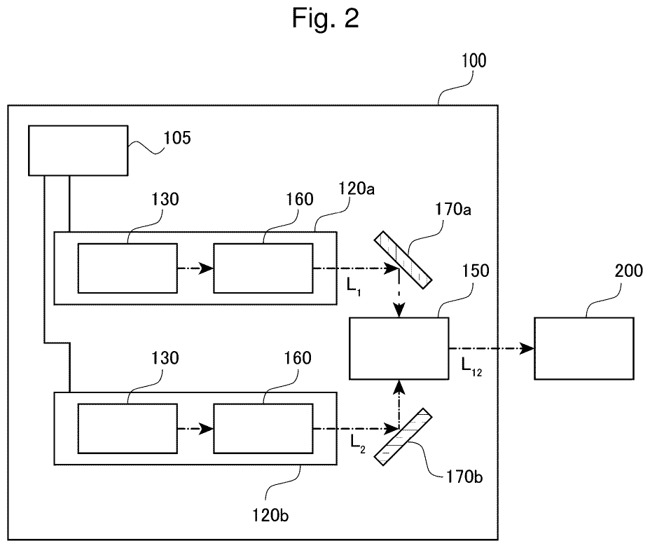

FIG. 2 is a schematic diagram illustrating a schematic configuration example of the entire laser system 100 of the present example. The laser system 100 includes a first pulse laser apparatus 120a and a second pulse laser apparatus 120b. The first pulse laser apparatus 120a and the second pulse laser apparatus 120b have the same configuration and include a laser oscillator 130 which is a master oscillator and an amplifier 160 which is a power oscillator. Further, the first pulse laser apparatus 120a and the second pulse laser apparatus 120b respectively output pulse laser beams L₁ and L₂ of a predetermined cycle.

The first pulse laser apparatus 120a and the second pulse laser apparatus 120b are, for example, ArF excimer laser apparatuses using a mixed gas including argon (Ar), fluorine (F₂), and neon (Ne). The ArF excimer laser apparatuses output a laser beam having a center wavelength of about 193.4 nm. The first pulse laser apparatus 120a and the second pulse laser apparatus 120b may be, for example, KrF excimer laser apparatuses using a mixed gas including krypton (Kr), F₂, and Ne. The KrF excimer laser apparatuses output a laser beam having a center wavelength of about 248.3 nm.

The laser system 100 further includes a beam combiner 150 that guides the first pulse laser beam L₁ and the second pulse laser beam L₂ to a same optical path, and reflective mirrors 170a and 170b that reflect the first pulse laser beam L₁ from the first pulse laser apparatus 120a and the second pulse laser beam L₂ from the second pulse laser apparatus 120b toward the beam combiner 150.

The beam combiner 150 outputs the first pulse laser beam L₁ and the second pulse laser beam L₂, which have entered the beam combiner 150 via the reflective mirrors 170a and 170b, on the same optical path. The beam combiner 150 may perform spatial beam coupling or polarized beam coupling of the first pulse laser beam L₁ and the second pulse laser beam L₂.

A processor 105 is a processing device including a storage device in which a control program is stored, and a central processing unit (CPU) which executes the control program. The processor 105 is specifically configured or programmed to execute various kinds of processing included in the present disclosure. The first and second pulse laser apparatuses 120a and 120b are controlled by the processor 105, and the processor 105 causes the first and second pulse laser beams L₁ and L₂ to be shifted by ½ of the predetermined cycle and be output. Therefore, the first and second pulse laser beams L₁ and L₂ are alternately output. The optical paths of the first and second pulse laser beams L₁ and L₂ are overlapped by the beam combiner 150, and a pulse laser beam is output from the laser system 100 at a repetition frequency twice as high as that of a single pulse laser apparatus.

In the present specification, a laser beam in a state where optical paths of pulse laser beams from a plurality of pulse laser apparatuses are at least partially overlapped such that the pulse laser beams travel in the same direction is referred to as pulse coupled light. Accordingly, the pulse laser beam formed of the first pulse laser beam L₁ and the second pulse laser beam L₂ output from the beam combiner 150 is pulse coupled light L₁₂.

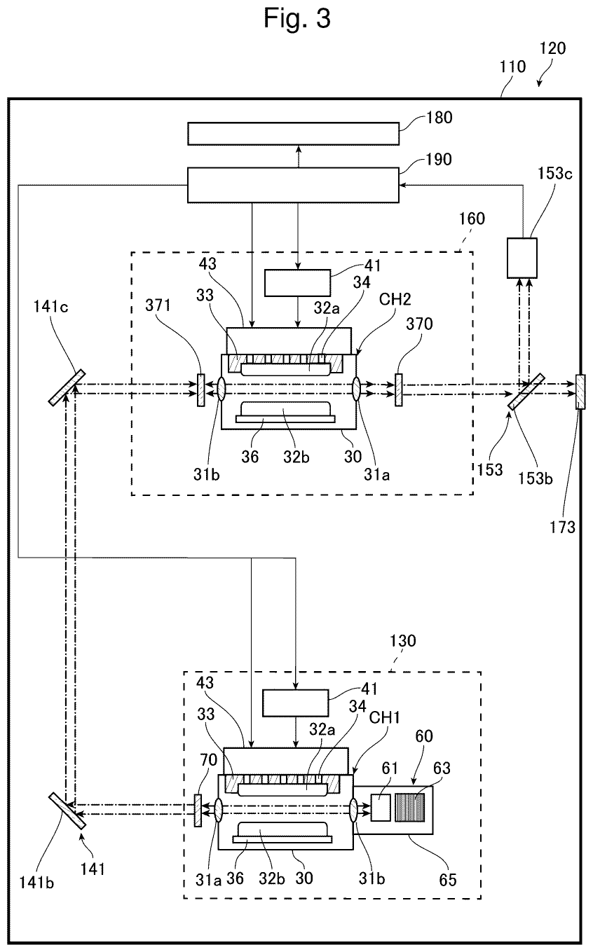

Next, the configuration of a pulse laser apparatus 120 that represents the first pulse laser apparatus 120a and the second pulse laser apparatus 120b having the same configuration is illustrated in FIG. 3. The pulse laser apparatus 120 mainly includes a housing 110, and the laser oscillator 130 that is a master oscillator, an optical transmission unit 141, the amplifier 160 that is a power oscillator, a detection unit 153, a display unit 180, and a processor 190 that are disposed in an internal space of the housing 110.

The laser oscillator 130 mainly includes a chamber device CH1, a charger 41, a pulse power module 43, a line narrowing module 60, and an output coupling mirror 70.

FIG. 3 illustrates an internal configuration of the chamber device CH1 viewed from a direction substantially perpendicular to a propagation direction of a laser beam. The chamber device CH1 mainly includes a housing 30, a pair of windows 31a and 31b, a pair of electrodes 32a and 32b, an insulating portion 33, a feedthrough 34, and an electrode holder portion 36.

The housing 30 encloses a laser gas in the internal space. The internal space is a space where light is generated by excitation of a laser medium in the laser gas. This light is propagated to the windows 31a and 31b.

The window 31a is disposed on a front-side wall surface of the housing 30 in the propagation direction of the laser beam from the laser system 100 to the exposure apparatus 200, and the window 31b is disposed on a rear-side wall surface of the housing 30 in the propagation direction. The windows 31a and 31b are made of, for example, a calcium fluoride substrate and surfaces of the windows 31a and 31b on an inner side and an outer side of the housing 30 are planar. The windows 31a and 31b are not limited to the calcium fluoride substrate as long as they can transmit the laser beam.

The electrodes 32a and 32b are disposed to face each other in the internal space of the housing 30, and a longitudinal direction of the electrodes 32a and 32b is along the propagation direction of light generated by a high voltage applied between the electrode 32a and the electrode 32b. A discharge space between the electrode 32a and the electrode 32b in the housing 30 is sandwiched between the window 31a and the window 31b. The electrodes 32a and 32b are discharge electrodes for exciting the laser medium by glow discharge. In the present example, the electrode 32a is a cathode and the electrode 32b is an anode.

The electrode 32a is supported by the insulating portion 33. The insulating portion 33 closes an opening formed in the housing 30. The insulating portion 33 includes an insulator. In addition, the feedthrough 34 formed of a conductive member is disposed in the insulating portion 33. The feedthrough 34 applies a voltage supplied from the pulse power module 43 to the electrode 32a. The electrode 32b is supported by the electrode holder portion 36 and is electrically connected to the electrode holder portion 36.

The charger 41 is a DC power supply device that charges an unillustrated capacitor provided inside the pulse power module 43 with a predetermined voltage. The charger 41 is disposed outside the housing 30 and is connected to the pulse power module 43. The pulse power module 43 includes an unillustrated switch controlled by the processor 190. The pulse power module 43 is a voltage application circuit that, when the switch is turned from OFF to ON by the control, boosts the voltage applied from the charger 41 to generate a pulsed high voltage, and applies the high voltage to the electrodes 32a and 32b. When the high voltage is applied, discharge occurs between the electrode 32a and the electrode 32b. By energy of the discharge, the laser medium in the housing 30 is excited. When the excited laser gas shifts to a ground level, light is output, and the output light passes through the windows 31a and 31b and is output to the outside of the housing 30. The windows 31a and 31b are inclined to form a Brewster's angle with respect to the propagation direction of the laser beam so as to suppress reflection of P-polarized light of the laser beam, and in the present example, are inclined with respect to a direction perpendicular to the propagation direction of the laser beam and a direction in which the electrodes 32a and 32b face each other. Therefore, the laser beam output from the chamber device CH1 includes predetermined linearly-polarized light having a polarization direction perpendicular to the direction in which the electrodes 32a and 32b face each other, and the linearly-polarized light having a polarization direction different from the polarization direction of the predetermined linearly-polarized light is reduced from the laser beam.

The line narrowing module 60 includes a housing 65, and a prism 61, a grating 63, and an unillustrated rotation stage that are disposed in an internal space of the housing 65. An opening is formed in the housing 65, and the housing 65 is connected to a rear side of the housing 30 through the opening.

The prism 61 widens a beam width of the light output from the window 31b and makes the light enter the grating 63. Further, the prism 61 reduces a beam width of reflected light from the grating 63 and returns the light to the internal space of the housing 30 through the window 31b. The prism 61 is supported by the rotation stage and is rotated by the rotation stage. By rotation of the prism 61, an incident angle of the light to the grating 63 is changed, and a wavelength of the light returning from the grating 63 to the housing 30 through the prism 61 can be selected. While FIG. 3 illustrates an example in which one prism 61 is disposed, two or more prisms may be disposed.

A surface of the grating 63 is formed of a material having a high reflectance, and many grooves are provided on the surface at predetermined intervals. The grating 63 is a dispersive optical element. A cross-sectional shape of each groove is, for example, a right-angled triangle. The light entering the grating 63 from the prism 61 is reflected by the grooves and is also diffracted in a direction corresponding to the wavelength of the light. The grating 63 is disposed in Littrow arrangement such that the incident angle of the light entering the grating 63 from the prism 61 coincides with a diffracting angle of diffracted light having a desired wavelength. Thus, the light of the desired wavelength is returned to the housing 30 through the prism 61.

The output coupling mirror 70 transmits a part of the laser beam output from the window 31a, and reflects the other part back into the internal space of the housing 30 through the window 31a. The output coupling mirror 70 is fixed to an unillustrated holder, and is disposed in the internal space of the housing 110.

The grating 63 and the output coupling mirror 70 provided across the housing 30 form a Fabry-Perot resonator, and the housing 30 is disposed on an optical path of the resonator.

The optical transmission unit 141 mainly includes high reflective mirrors 141b and 141c. The high reflective mirrors 141b and 141c are fixed to respective unillustrated holders in a state where respective inclination angles are adjusted, and are disposed in the internal space of the housing 110. The high reflective mirrors 141b and 141c highly reflect the laser beam. The high reflective mirrors 141b and 141c are disposed on an optical path of the laser beam transmitted through the output coupling mirror 70. The laser beam is reflected by the high reflective mirrors 141b and 141c and is propagated to a rear mirror 371 of the amplifier 160. At least a part of the laser beam is transmitted through the rear mirror 371.

The amplifier 160 amplifies energy of the laser beam output from the laser oscillator 130. A basic configuration of the amplifier 160 is substantially the same as that of the laser oscillator 130. Therefore, the configuration same as that of the laser oscillator 130 is denoted by the same sign, and detailed description is omitted unless specific description is needed. The electrodes 32a and 32b generate discharge for amplifying the laser beam from the laser oscillator 130. The direction in which the electrodes 32a and 32b face each other is a direction perpendicular to the polarization direction of the linearly-polarized light in the laser beam from the laser oscillator 130. The windows 31a and 31b are inclined with respect to the polarization direction of the predetermined linearly-polarized light such that the linearly-polarized light in the laser beam enters as the P-polarized light and the incident angle of the laser beam becomes the Brewster's angle. Therefore, a laser beam output from a chamber device CH2 includes the predetermined linearly-polarized light, and the linearly-polarized light in the polarization direction different from the polarization direction of the predetermined linearly-polarized light is reduced from the laser beam.

The amplifier 160 differs from the laser oscillator 130 in that it does not include the line narrowing module 60 but includes the rear mirror 371. The rear mirror 371 is provided between the high reflective mirror 141c and the window 31b. The rear mirror 371 transmits a part of the laser beam from the laser oscillator 130 toward the discharge space between the electrodes 32a and 32b, and reflects a part of the laser beam amplified in the chamber device CH2 back to the discharge space of the chamber device CH2.

An output coupling mirror 370 is disposed on a side opposite to the rear mirror 371 with respect to the chamber device CH2. The output coupling mirror 370 reflects a part of the laser beam from the chamber device CH2 and transmits the other part of the laser beam. Therefore, a partial reflective film having a predetermined reflectance is coated on a surface of the output coupling mirror 370 on the side of the chamber device CH2.

The detection unit 153 mainly includes a beam splitter 153b and a photosensor 153c.

The beam splitter 153b is disposed on an optical path of the laser beam transmitted through the output coupling mirror 370. The beam splitter 153b transmits the laser beam transmitted through the output coupling mirror 370 toward an exit window 173 with a high transmittance, and reflects a part of the laser beam toward a light receiving surface of the photosensor 153c.

The photosensor 153c measures pulse energy of the laser beam incident on the light receiving surface of the photosensor 153c. The photosensor 153c is electrically connected to the processor 190, and outputs a signal indicating the measured pulse energy to the processor 190. The processor 190 controls a voltage to be applied to the electrodes 32a and 32b of the amplifier 160 based on the signal.

The exit window 173 is provided on the side opposite to the output coupling mirror 370 with respect to the beam splitter 153b of the detection unit 153. The exit window 173 is provided on a wall of the housing 110. The light transmitted through the beam splitter 153b is output from the exit window 173 to the exposure apparatus 200 outside the housing 110. The laser beam is a pulse laser beam having a center wavelength of 193.4 nm, for example.

The display unit 180 is a monitor that displays a state of control by the processor 190 based on a signal from the processor 190. The display unit 180 may be disposed outside the housing 110.

The processor 190 of the present disclosure is a processing device having a configuration similar to that of the processor 105. The processor 190 is specifically configured or programmed to perform various kinds of processing included in the present disclosure.

### 2.2 Operation

Next, the operation of the pulse laser apparatus 120 will be described.

When the pulse laser apparatus 120 outputs a laser beam, the processor 190 receives a signal indicating target energy Et and a light emission trigger signal from an unillustrated exposure processor of the exposure apparatus 200, for example, via the processor 105. The target energy Et has a target value for the energy of the laser beam used in the exposure process. The processor 190 sets a predetermined charging voltage to the charger 41 of the amplifier 160 such that energy E becomes the target energy Et, and turns ON the switch of the pulse power module 43 of the laser oscillator 130 in synchronization with the light emission trigger signal. Thus, the pulse power module 43 generates a pulsed high voltage from electric energy held in the charger 41, and a high voltage is applied between the electrode 32a and the electrode 32b of the laser oscillator 130. When the high voltage is applied, the discharge occurs between the electrode 32a and the electrode 32b, the laser medium contained in the laser gas between the electrode 32a and the electrode 32b is turned to an excited state, and light is discharged when the laser medium returns to a ground state. The discharged light resonates between the grating 63 and the output coupling mirror 70 of the laser oscillator 130 and is amplified every time it passes through the discharge space in the internal space of the housing 30, and laser oscillation occurs. The laser beam includes the predetermined linearly-polarized light, and the linearly-polarized light in the polarization direction different from the polarization direction of the predetermined linearly-polarized light is reduced from the laser beam when the laser beam is transmitted through the windows 31a and 31b. A part of the laser beam is transmitted through the output coupling mirror 70 and is reflected by the high reflective mirrors 141b and 141c, and the laser beam is propagated into the amplifier 160. The laser beam is transmitted through the rear mirror 371 and the windows 31a and 31b in the amplifier 160 and travels and propagates in the housing 30 of the amplifier 160.

The processor 190 turns ON the switch of the pulse power module 43 of the amplifier 160 such that the discharge occurs when the laser beam from the laser oscillator 130 is propagated to the discharge space in the housing 30 of the amplifier 160. That is, the processor 190 controls the pulse power module 43 such that a high voltage is applied to the electrodes 32a and 32b of the amplifier 160 after a lapse of predetermined delay time with respect to a timing at which the switch of the pulse power module 43 is turned ON.

As a result, the laser beam that enters the amplifier 160 is amplified in the amplifier 160. In addition, the laser beam propagated to the internal space of the housing 30 is propagated to the output coupling mirror 370 through the window 31a as described above, and is reflected by the output coupling mirror 370. The laser beam reflected by the output coupling mirror 370 is propagated through the window 31a to the internal space of the housing 30 and is output from the window 31b. The light output from the window 31b is reflected by the rear mirror 371 and is propagated through the window 31b to the internal space of the housing 30. In this way, the laser beam of a predetermined wavelength reciprocates between the rear mirror 371 and the output coupling mirror 370. The laser beam includes the predetermined linearly-polarized light, and the linearly-polarized light in the polarization direction different from the polarization direction of the predetermined linearly-polarized light is reduced from the laser beam when the laser beam is transmitted through the windows 31a and 31b. Further, the laser beam is amplified every time it passes through the discharge space inside the housing 30.

A part of the laser beam from the chamber device CH2 of the amplifier 160 is transmitted through the output coupling mirror 370 and is propagated to the beam splitter 153b.

A part of the amplified laser beam propagated to the beam splitter 153b is transmitted through the beam splitter 153b and the exit window 173 and is propagated to the exposure apparatus 200, and the other part is reflected by the beam splitter 153b and is propagated to the photosensor 153c.

The photosensor 153c measures the energy E of the received amplified laser beam. The photosensor 153c outputs a signal indicating measured energy E to the processor 190. The processor 190 feedback-controls the charging voltage of the charger 41 such that a difference ΔE between the energy E and the target energy Et is within an allowable range. The laser beam having the difference ΔE within the allowable range is transmitted through the beam splitter 153b and the exit window 173 and is output.

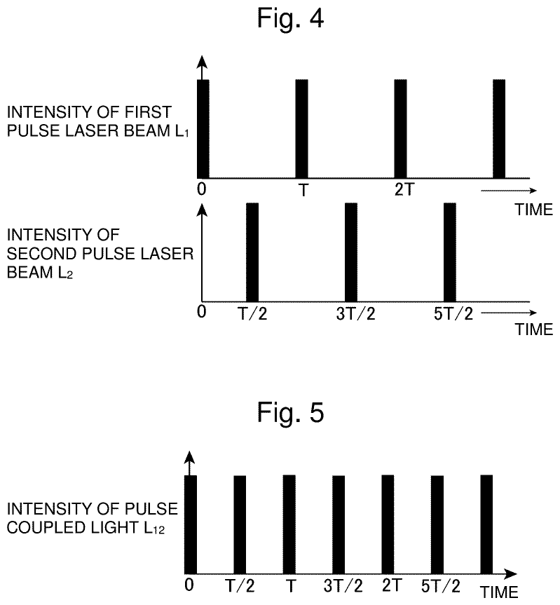

Referring back to FIG. 2, the operation of the laser system 100 of the comparative example will be further described. FIG. 4 is a timing chart illustrating a relation between an output timing of the first pulse laser beam L₁ of the first pulse laser apparatus 120a and an output timing of the second pulse laser beam L₂ of the second pulse laser apparatus 120b in the present example. A horizontal axis represents time, and a vertical axis represents intensity of the pulse laser beam. The same applies to other timing charts described below.

As described above, the first pulse laser apparatus 120a and the second pulse laser apparatus 120b respectively output the first and second pulse laser beams L₁ and L₂ of the predetermined cycle, and the first and second pulse laser beams L₁ and L₂ are shifted by ½ of the predetermined cycle from each other. Assuming that T is the predetermined cycle in which the first and second pulse laser beams L₁ and L₂ are output, phases are shifted from each other by a half cycle T/2. The processor 105 controls the first and second pulse laser apparatuses 120a and 120b to alternately output the respective first and second pulse laser beams L₁ and L₂ as described above.

The first pulse laser beam L₁ output from the first pulse laser apparatus 120a is reflected by the reflective mirror 170a and enters the beam combiner 150. The second pulse laser beam L₂ output from the second pulse laser apparatus 120b is reflected by the reflective mirror 170b and enters the beam combiner 150. The beam combiner 150 outputs the first pulse laser beam L₁ and the second pulse laser beam L₂ on the same optical path.

FIG. 5 is a timing chart illustrating an output timing of the pulse coupled light L₁₂ output from the beam combiner 150. The first pulse laser beam L₁ output from the first pulse laser apparatus 120a and the second pulse laser beam L₂ output from the second pulse laser apparatus 120b are alternately output from the beam combiner 150. That is, the beam combiner 150 outputs the pulse coupled light L₁₂ which is a train of pulse laser beams in the cycle T/2.

Thus, the pulse coupled light L₁₂ is output from the laser system 100 at a repetition frequency twice as high as that of a single pulse laser apparatus.

### 2.3 Problem

With increase in throughput of the exposure apparatus 200, a demand for higher output is increasing for the laser system 100 as a light source. However, when the beam combiner 150 is a spatial beam coupling system, a coupled beam size or beam divergence may become large. In a case of not changing design of the exposure apparatus, an event like not being able to use a part of the beam may occur when the beam size or the beam divergence becomes large. Therefore, there is a need to suppress the beam size or the size of the beam divergence so as not to change the design of the exposure apparatus. In addition, even in a case of newly designing the exposure apparatus, there is a need to suppress the beam size or the size of the beam divergence so as to suppress enlargement of the exposure apparatus and to further facilitate the design and manufacture of the exposure apparatus.

In addition, when the beam combiner 150 is a polarized beam coupling system, two different kinds of polarized light are provided to the exposure apparatus, and it may be inappropriate for exposure.

The following embodiments illustrate a laser system in which a plurality of pulse laser beams output from a plurality of pulse laser apparatuses can be laser beams suitable for exposure.

### 3. Description of Laser System of Embodiment 1

The laser system 100 of Embodiment 1 will be described. Any components same as those described above are denoted by same signs, and any redundant description thereof is omitted unless specific description is needed.

### 3.1 Configuration

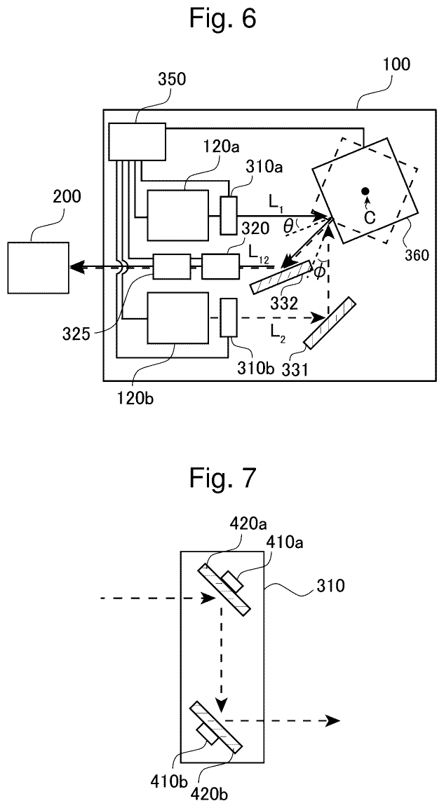

FIG. 6 is a schematic diagram illustrating a schematic configuration example of the laser system 100 of Embodiment 1. As illustrated in FIG. 6, the laser system 100 of the present embodiment mainly differs from the laser system 100 of the comparative example in that it includes a first polygon mirror 360 configured to reflect the first pulse laser beam L₁ and the second pulse laser beam L₂, and a processor 350 configured to control an output timing of the first pulse laser beam L₁, an output timing of the second pulse laser beam L₂, and a rotation angle of the first polygon mirror 360 so as to reflect the first pulse laser beam L₁ and the second pulse laser beam L₂ in a same first direction. The first and second pulse laser apparatuses 120a and 120b respectively output the first and second pulse laser beams L₁ and L₂ of a same frequency in the same manner as in the comparative example.

Note that the first pulse laser apparatus 120a and the second pulse laser apparatus 120b may be formed of the laser oscillator 130 which is a master oscillator and the amplifier 160 which is a power oscillator as in the comparative example, or may be formed only of the laser oscillator 130 without being provided with the amplifier 160.

The laser system 100 of the present embodiment includes the processor 350 instead of the processor 105. The processor 350 is a processing device similar to the processor 105. The processor 350 is specifically configured or programmed to execute various kinds of processing included in the present embodiment. Further, the processor 350 is electrically connected to the processors 190 included in the first and second pulse laser apparatuses 120a and 120b and an unillustrated exposure processor of the exposure apparatus 200, and transmits and receives various kinds of signals to/from the respective processors.

The first polygon mirror 360 includes N reflective mirrors for which an angle formed by the mirrors adjacent to each other is fixed. N is a natural number of three or larger. In the present embodiment, an example in which N is four is illustrated. The first polygon mirror 360 is connected to an unillustrated drive unit and is rotated at a substantially constant speed with a center axis C as a rotation axis. When a repetition frequency of the first pulse laser beam L₁ output from the first pulse laser apparatus 120a and the second pulse laser beam L₂ output from the second pulse laser apparatus 120b is X [Hz], a rotation number per unit time of the first polygon mirror 360 is preferably X/N [rps]. In the present embodiment, since N is four, the rotation number per unit time of the first polygon mirror 360 is X/4 [rps]. However, the rotation number per unit time of the first polygon mirror 360 including N reflective mirrors is not limited to X/N [rps], and may be 2X/N [rps], for example. The drive unit of the first polygon mirror 360 is electrically connected to the processor 350, and a rotation speed of the first polygon mirror 360 is controlled by the processor 350.

An incident angle θ of the first pulse laser beam L₁ coming from the first pulse laser apparatus 120a on the first polygon mirror 360 and an incident angle ϕ of the second pulse laser beam L₂ coming from the second pulse laser apparatus 120b on the first polygon mirror 360 are preferably the same angle. In a case where the incident angles θ and ϕ are the same angle, the incident angle is preferably 360/4N° when the first polygon mirror 360 includes N reflective mirrors. In the present embodiment, since N is four, the incident angle satisfies θ=ϕ=22.5°.

Each reflective mirror of the first polygon mirror 360 is formed of, for example, a multilayer film. In this case, each reflective mirror is formed so as to reflect the first and second pulse laser beams L₁ and L₂ from the first and second pulse laser apparatuses 120a and 120b at a high reflectance when they are incident at a predetermined incident angle. Therefore, in the present example, it is preferable that each reflective mirror have the highest reflectance at the incident angle of 22.5°.

The first pulse laser beam L₁ and the second pulse laser beam L₂ reflected by the first polygon mirror 360 are propagated in the same first direction. Further, optical paths of the first pulse laser beam L₁ and the second pulse laser beam L₂ reflected by the first polygon mirror 360 are at least partially overlapped. Therefore, the pulse coupled light L₁₂ is provided from the first polygon mirror 360.

The laser system 100 of the present embodiment further includes beam steering devices 310a and 310b provided in the optical paths of the first and second pulse laser beams L₁ and L₂ that are output from the first pulse laser apparatus 120a and the second pulse laser apparatus 120b and enter the first polygon mirror 360, and configured to adjust the optical paths of the first and second pulse laser beams L₁ and L₂. That is, the beam steering devices 310a and 310b are provided upstream of the first polygon mirror 360.

Since the beam steering devices 310a and 310b have the same configuration, the beam steering devices 310a and 310b will be described as a beam steering device 310. FIG. 7 is a schematic diagram illustrating a schematic configuration example of the beam steering device 310. The beam steering device 310 includes reflective mirrors 420a and 420b and actuators 410a and 410b that change directions of the reflective mirrors 420a and 420b, respectively. The actuators 410a and 410b are electrically connected to the processor 350, and at least one of a position and an angle is controlled by the processor 350 to adjust the optical paths of the first and second pulse laser beams L₁ and L₂ output from the beam steering device 310.

Note that the beam steering device 310 may be provided between one of the first pulse laser apparatus 120a and the second pulse laser apparatus 120b and the first polygon mirror 360, and may not be provided on the optical path of the other thereof. In addition, when the first and second pulse laser beams L₁ and L₂ are output from the first and second pulse laser apparatuses 120a and 120b in appropriate directions, the laser system 100 may not include the beam steering device 310.

In the present embodiment, the laser system 100 includes a mirror 331 configured to reflect the second pulse laser beam L₂, and the second pulse laser beam L₂ output from the second pulse laser apparatus 120b and made to pass through the beam steering device 310b is reflected by the mirror 331 and is incident on the first polygon mirror 360.

Further, the laser system 100 of the present embodiment includes a beam measuring instrument 320 configured to measure at least one of a beam position and a pointing (direction) of the first and second pulse laser beams L₁ and L₂ reflected by the first polygon mirror 360.

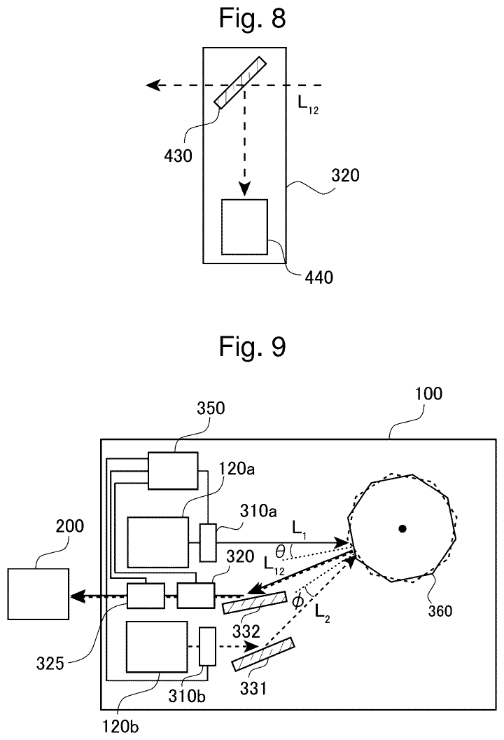

FIG. 8 is a schematic diagram illustrating a schematic configuration example of the beam measuring instrument 320. The beam measuring instrument 320 includes a beam splitter 430 and a photosensor 440. The beam splitter 430 reflects a part of the pulse coupled light L₁₂ toward the photosensor 440 and transmits the other part. The photosensor 440 is electrically connected to the processor 350. The photosensor 440 includes a light receiving surface for receiving light, measures at least one of the beam position and the pointing on the light receiving surface, and transmits a measurement result to the processor 350. The beam measuring instrument 320 is preferably further capable of measuring pulse energy, power, a wavelength, a spectrum, and the like.

The processor 350 controls the beam steering devices 310a and 310b such that the optical path of the first pulse laser beam L₁ reflected by the first polygon mirror 360 and the optical path of the second pulse laser beam L₂ reflected by the first polygon mirror 360 approach each other based on the measurement result of the beam measuring instrument 320. Further, the processor 350 controls the first pulse laser apparatus 120a, the second pulse laser apparatus 120b, the beam steering device 310a, the beam steering device 310b, and the first polygon mirror 360 based on the measurement results measured in the beam measuring instrument 320, and adjusts the intensity and the optical path of the pulse coupled light L₁₂ so as to obtain optimum beam power for the exposure apparatus 200.

Note that the beam measuring instrument 320 may be provided outside the laser system 100. In addition, the laser system 100 may not include the beam measuring instrument 320.

In the present embodiment, the laser system 100 includes a mirror 332 configured to reflect the pulse coupled light L₁₂, and the pulse coupled light L₁₂ from the first polygon mirror 360 is reflected by the mirror 332 and enters the beam measuring instrument 320.

Further, in the present embodiment, a pulse stretcher 325 configured to temporally widen a pulse width of the first pulse laser beam L₁ and the second pulse laser beam L₂ is provided on an optical path through which the pulse coupled light L₁₂ is propagated. That is, the pulse stretcher 325 is provided downstream of the first polygon mirror 360. The pulse stretcher 325 includes, for example, a beam splitter that is disposed on the optical path of the pulse coupled light L₁₂ and reflects and splits a part of the pulse coupled light L₁₂, and a plurality of reflective mirrors that reflect the split pulse coupled light L₁₂ a plurality of times and delay the pulse coupled light L₁₂ transmitted through the beam splitter. The delayed pulse coupled light L₁₂ is returned on the same optical path as the optical path of the pulse coupled light L₁₂ transmitted through the beam splitter.

The pulse stretcher 325 may be provided upstream of the first polygon mirror 360, but is preferably provided downstream of the first polygon mirror 360. When the pulse stretcher 325 is provided upstream of the first polygon mirror 360, the first and second pulse laser beams L₁ and L₂ having the widened temporal pulse widths are reflected by the rotating first polygon mirror 360 causing a risk of that the optical paths of the reflected first and second pulse laser beams L₁ and L₂ are easily shifted. On the other hand, when the pulse stretcher 325 is provided downstream of the first polygon mirror 360, the first and second pulse laser beams L₁ and L₂ before having the temporal pulse width widened are reflected by the first polygon mirror 360 such that the first pulse laser beam L₁ and the second pulse laser beam L₂ are easily reflected in the same direction. Note that the pulse stretcher 325 may not be provided.

In the present embodiment, as illustrated in FIG. 6, an output direction of the first pulse laser beam L₁ output from the first pulse laser apparatus 120a and an output direction of the second pulse laser beam L₂ output from the second pulse laser apparatus 120b are opposite to an output direction of the pulse coupled light L₁₂ formed of the first and second pulse laser beams L₁ and L₂ output from the laser system 100. By outputting the first pulse laser beam L₁ and the second pulse laser beam L₂ in this way, it is possible to suppress the number of mirrors or the like that reflect the first pulse laser beam L₁ and the second pulse laser beam L₂, to improve efficiency of layout, and to make the laser system 100 smaller. However, the output direction of the first pulse laser beam L₁ output from the first pulse laser apparatus 120a and the output direction of the second pulse laser beam L₂ output from the second pulse laser apparatus 120b may not be opposite to the output direction of the pulse coupled light L₁₂ output from the laser system 100.

### 3.2 Operation

The processor 350 outputs the first and second pulse laser beams L₁ and L₂ from the first and second pulse laser apparatuses 120a and 120b in the same manner as in the comparative example. Therefore, the first and second pulse laser beams L₁ and L₂ are output with a shift of ½ of the predetermined cycle T between them, as illustrated in FIG. 4. The first and second pulse laser beams L₁ and L₂ output from the first and second pulse laser apparatuses 120a and 120b have their optical paths adjusted by the beam steering devices 310a and 310b, enter the first polygon mirror 360, and are reflected by a reflective surface of the first polygon mirror 360.

Here, it is assumed that an angle formed by the first pulse laser beam L₁ incident on the first polygon mirror 360 and the second pulse laser beam L₂ incident on the first polygon mirror 360 is 90°. In FIG. 6, a state of the first polygon mirror 360 at a timing at which the first pulse laser beam L₁ is incident thereon is indicated by a solid line, and a state of the first polygon mirror 360 at a timing at which the second pulse laser beam L₂ is incident thereon is indicated by a broken line. The two states of the first polygon mirror 360 are relatively rotated by 45°. In addition, in this case, when spatial absolute coordinates of a position where the first pulse laser beam L₁ is incident on the first polygon mirror 360 and spatial absolute coordinates of a position where the second pulse laser beam L₂ is incident on the first polygon mirror 360 coincide with each other, an optical path through which the first pulse laser beam L₁ reflected by the first polygon mirror 360 is propagated and an optical path through which the second pulse laser beam L₂ reflected by the first polygon mirror 360 is propagated are the same optical path. That is, optical axes coincide with each other. Even when the first pulse laser beam L₁ and the second pulse laser beam L₂ are reflected by the same reflective surface, a reflecting position of the first pulse laser beam L₁ and a reflecting position of the second pulse laser beam L₂ on the reflective surface may be different from each other.

The processor 350 controls the output timing of the first pulse laser apparatus 120a, the output timing of the second pulse laser apparatus 120b, and the rotation angle of the first polygon mirror 360 such that the first and second pulse laser beams L₁ and L₂ reflected by the first polygon mirror 360 are reflected in the same first direction. As a result, as illustrated in FIG. 6, the pulse laser beams become the pulse coupled light L₁₂ and are propagated on the same optical path. Note that the optical paths of the first and second pulse laser beams L₁ and L₂ are only required to be oriented in the same first direction and at least partially overlapped, and the optical axes may not completely coincide with each other. However, it is preferable that the optical axis of the first pulse laser beam L₁ reflected by the first polygon mirror 360 coincide with the optical axis of the second pulse laser beam L₂. In addition, the same first direction may vary in a range of 0.1°.

In the present embodiment, the first polygon mirror 360 reflects the first and second pulse laser beams L₁ and L₂ in the first direction between the incoming first and second pulse laser beams L₁ and L₂. The pulse coupled light L₁₂ that is the first and second pulse laser beams L₁ and L₂ reflected by the first polygon mirror 360 is propagated between the optical paths of the first and second pulse laser beams L₁ and L₂ incident on the first polygon mirror 360, and is propagated between the first pulse laser apparatus 120a and the second pulse laser apparatus 120b.

The pulse coupled light L₁₂ from the first polygon mirror 360 enters the beam measuring instrument 320 via the mirror 332. The processor 350 controls the beam steering device 310 such that the beam position and the pointing of the pulse coupled light L₁₂ are within a predetermined range based on the measurement result measured by the beam measuring instrument 320. That is, the processor 350 controls the beam steering device 310 such that the optical paths of the first pulse laser beam L₁ and the second pulse laser beam L₂ reflected by the first polygon mirror 360 approach each other based on the measurement result of the beam measuring instrument 320. The beam measuring instrument 320 may measure the pulse energy, the power, the wavelength, and the spectrum of each pulse laser light.

The pulse coupled light L₁₂ transmitted through the beam measuring instrument 320 enters the pulse stretcher 325 to have the temporal pulse width widened, and is output from the pulse stretcher 325.

In this way, the laser system 100 outputs the pulse coupled light L₁₂ having a repetition frequency twice as high as that of the first and second pulse laser beams L₁ and L₂.

### 3.3 Effect and Advantage

The laser system 100 includes the first pulse laser apparatus 120a configured to output the first pulse laser beam L₁ in the predetermined cycle T, the second pulse laser apparatus 120b configured to output the second pulse laser beam L₂ in the predetermined cycle T, the first polygon mirror 360 configured to reflect the first pulse laser beam L₁ and the second pulse laser beam L₂, and the processor 350 configured to control the first pulse laser apparatus 120a, the second pulse laser apparatus 120b, and the first polygon mirror 360 such that the first pulse laser beam L₁ and the second pulse laser beam L₂ are output with a shift of ½ of the predetermined cycle T between them, and the optical paths of the first pulse laser beam L₁ and the second pulse laser beam L₂ reflected by the first polygon mirror 360 are oriented in the same first direction and at least partially overlapped.

The laser system 100 of the present embodiment can output the pulse coupled light L₁₂ at the repetition frequency twice as high as that of a single pulse laser apparatus. In addition, an increase in the beam size and the beam divergence of the pulse coupled light L₁₂ formed of the first and second pulse laser beams L₁ and L₂ can be suppressed. Further, the polarization direction of the pulse coupled light L₁₂ can be fixed. Therefore, the laser system 100 of the present embodiment can output a laser beam appropriate for exposure. Further, since the first and second pulse laser beams L₁ and L₂ can be reflected at the same incident angle by the same polygon mirror and made into the pulse coupled light L₁₂, the energy and optical quality of the respective pulse laser beams of the pulse coupled light L₁₂ can be brought close to each other. In addition, the optical path of the pulse coupled light L₁₂ can be easily adjusted.

When the pulse coupled light L₁₂ is not propagated in a space between the first pulse laser apparatus 120a and the second pulse laser apparatus 120b and intersects the optical path of the laser beam output from one of the pulse laser apparatuses 120, an optical path pipe or the like that covers the optical path and brings surroundings of the laser beam into a predetermined atmosphere may intersect, and the configuration of the laser system 100 may become complicated. However, in the present embodiment, the first polygon mirror 360 reflects the first and second pulse laser beams L₁ and L₂ in the direction between the first and second pulse laser beams L₁ and L₂ incident on the first polygon mirror 360, and the pulse coupled light L₁₂ is propagated between the first pulse laser apparatus 120a and the second pulse laser apparatus 120b. Therefore, the pulse coupled light L₁₂ does not intersect the optical paths of the first and second pulse laser beams L₁ and L₂ incident on the first polygon mirror 360, and the configuration of the laser system 100 can be simplified.

### 3.4 Modification

Next, a modification of Embodiment 1 will be described. FIG. 9 is a schematic diagram illustrating a schematic configuration example of the laser system 100 of the present modification. The laser system 100 of the present modification differs from the laser system 100 of the embodiment in that the number of the reflective surfaces of the first polygon mirror 360 is different.

The number N of the reflective surfaces of the first polygon mirror 360 in the present modification is eight, and is larger than the number of the reflective surfaces of the first polygon mirror 360 in the embodiment. Therefore, the rotation number per unit time of the first polygon mirror 360 in the present modification can be smaller than the rotation number per unit time of the first polygon mirror 360 in the embodiment. For example, in the embodiment, since the number N of the reflective surfaces is four, when the repetition frequency of the first and second pulse laser beams L₁ and L₂ is X [Hz], the rotation number per unit time of the first polygon mirror 360 is X/4 [rps]. On the other hand, in the present modification, the rotation number per unit time of the first polygon mirror 360 can be X/8 [rps]. Since it is possible to further reduce the rotation number per unit time of the first polygon mirror 360 in this way, the control of the laser system 100 is facilitated. In addition, it is possible to reduce a change amount of an angle of the reflective surface while one pulse is being reflected by the reflective surface, and it is possible to suppress the shift of the optical paths of the first and second pulse laser beams L₁ and L₂ reflected by the first polygon mirror 360.

Here, the incident angle θ of the first pulse laser beam L₁ coming from the first pulse laser apparatus 120a on the first polygon mirror 360 and the incident angle ¢ of the second pulse laser beam L₂ coming from the second pulse laser apparatus 120b on the first polygon mirror 360 are preferably equal to each other. In a case where the incident angles θ and ϕ are equal, the incident angle is preferably 360/4N° when the first polygon mirror 360 includes N reflective mirrors. In the present modification, since N is eight, the incident angle satisfies θ=ϕ=11.25°.

The number N of the reflective mirrors of the first polygon mirror 360 is not limited to four or eight, and may be a natural number of three or larger.

### 4. Description of Laser System of Embodiment 2

The laser system 100 of Embodiment 2 will be described. Any components same as those described above are denoted by same signs, and any redundant description thereof is omitted unless specific description is needed.

### 4.1 Configuration

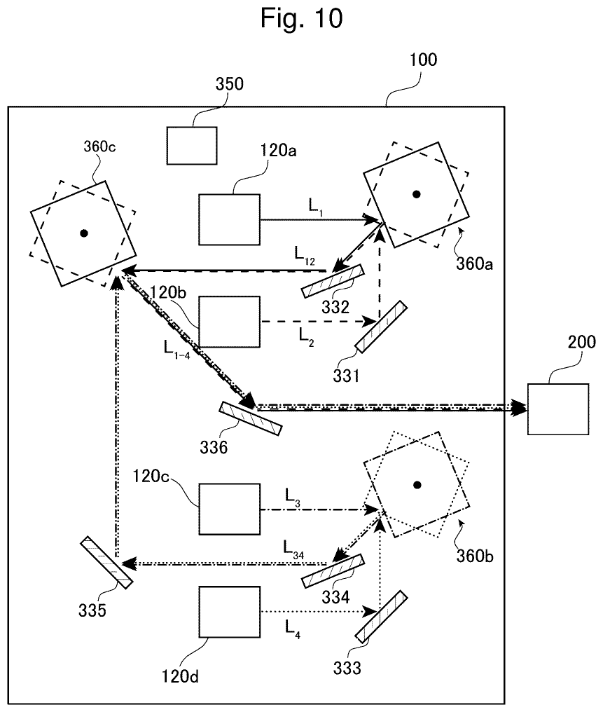

FIG. 10 is a schematic diagram illustrating a schematic configuration example of the laser system 100 of Embodiment 2. The laser system 100 of the present embodiment mainly differs from Embodiment 1 in that it includes first to fourth pulse laser apparatuses 120a to 120d and generates third pulse coupled light L₁₋₄ in three polygon mirrors of a first polygon mirror 360a, a second polygon mirror 360b, and a third polygon mirror 360c, while Embodiment 1 includes the two first and second pulse laser apparatuses 120a and 120b and generates the pulse coupled light L₁₂ in one first polygon mirror 360. In order to avoid complication of the drawing, electrical connection of the processor 350 is omitted in FIG. 10 and subsequent drawings.

The first polygon mirror 360a has a configuration similar to that of the first polygon mirror 360 of Embodiment 1, and similarly to Embodiment 1, reflects the first pulse laser beam L₁ and the second pulse laser beam L₂ in the first direction to generate first pulse coupled light L₁₂ similar to the pulse coupled light L₁₂ described in Embodiment 1.

The third and fourth pulse laser apparatuses 120c and 120d have a configuration similar to that of the first and second pulse laser apparatuses 120a and 120b, and output third and fourth pulse laser beams L₃ and L₄ in the predetermined cycle T. The third and fourth pulse laser beams L₃ and L₄ output from the third and fourth pulse laser apparatuses 120c and 120d are incident on the second polygon mirror 360b. In the present embodiment, the laser system 100 includes a mirror 333 configured to reflect the fourth pulse laser beam L₄, and the fourth pulse laser beam L₄ output from the fourth pulse laser apparatus 120d is reflected by the mirror 333 and is incident on the second polygon mirror 360b.

Note that a beam steering device configured to adjust an optical path may be provided, similarly to Embodiment 1, on at least one of optical paths from the first and second pulse laser apparatuses 120a and 120b to the first polygon mirror 360a and on at least one of optical paths from the third and fourth pulse laser apparatuses 120c and 120d to the second polygon mirror 360b.

The second polygon mirror 360b has a configuration similar to that of the first polygon mirror 360a, and reflects the third pulse laser beam L₃ and the fourth pulse laser beam L₄ in a second direction to generate the second pulse coupled light L₃₄.

The first pulse coupled light L₁₂ from the first polygon mirror 360a and the second pulse coupled light L₃₄ from the second polygon mirror 360b are incident on the third polygon mirror 360c. In the present embodiment, the first pulse coupled light L₁₂ is reflected by the mirror 332 and is incident on the third polygon mirror 360c. Further, in the present embodiment, the laser system 100 includes mirrors 334 and 335 configured to reflect the second pulse coupled light L₃₄, and the second pulse coupled light L₃₄ from the second polygon mirror 360b is reflected by the mirrors 334 and 335 and is incident on the third polygon mirror 360c.

The third polygon mirror 360c has a configuration similar to that of the first polygon mirror 360a, and reflects the first pulse coupled light L₁₂ and the second pulse coupled light L₃₄ in a third direction to generate the third pulse coupled light L₁₋₄. In the present embodiment, the laser system 100 includes a mirror 336 configured to reflect the third pulse coupled light L₁₋₄, and the third pulse coupled light L₁₋₄ from the third polygon mirror 360c is reflected by the mirror 336 and is output from the laser system 100. The beam measuring instrument 320 and the pulse stretcher 325 may be provided, similarly to Embodiment 1, on an optical path of the third pulse coupled light L₁₋₄.

The processor 350 of the present embodiment controls the first pulse laser apparatus 120a, the second pulse laser apparatus 120b, the third pulse laser apparatus 120c, the fourth pulse laser apparatus 120d, the first polygon mirror 360a, the second polygon mirror 360b, and the third polygon mirror 360c as described later.

### 4.2 Operation

In the present embodiment, the first polygon mirror 360a reflects the first and second pulse laser beams L₁ and L₂ in the first direction between the incoming first and second pulse laser beams L₁ and L₂. The pulse coupled light L₁₂ that is the first and second pulse laser beams L₁ and L₂ reflected by the first polygon mirror 360a is propagated between the optical paths of the first and second pulse laser beams L₁ and L₂ incident on the first polygon mirror 360a, and is propagated between the first pulse laser apparatus 120a and the second pulse laser apparatus 120b. Further, the second polygon mirror 360b reflects the third and fourth pulse laser beams L₃ and L₄ in the second direction between the incoming third and fourth pulse laser beams L₃ and L₄. The pulse coupled light L₃₄ that is the third and fourth pulse laser beams L₃ and L₄ reflected by the second polygon mirror 360b is propagated between the optical paths of the third and fourth pulse laser beams L₃ and L₄ incident on the second polygon mirror 360b, and is propagated between the third pulse laser apparatus 120c and the fourth pulse laser apparatus 120d. With such disposition, it is possible to suppress the number of mirrors, to improve efficiency of the layout, and to make the laser system 100 smaller.

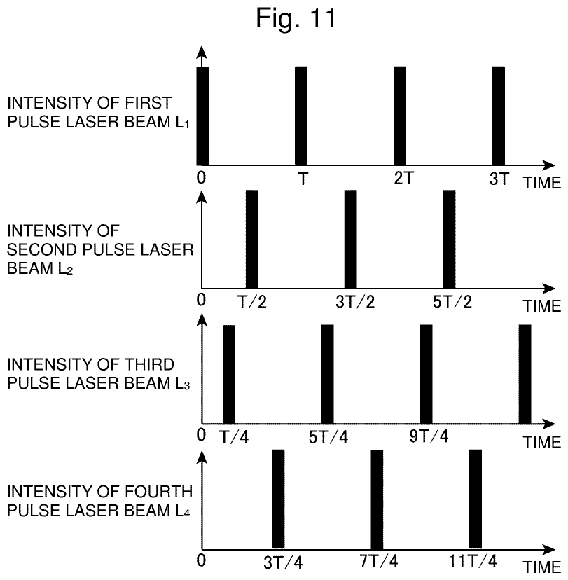

FIG. 11 is a timing chart illustrating a relation among output timings of the first to fourth pulse laser beams L₁ to L₄. The output timings of the first and second pulse laser beams L₁ and L₂ output from the first and second pulse laser apparatuses 120a and 120b are similar to that in Embodiment 1.

The output timings of the third and fourth pulse laser beams L₃ and L₄ output from the third and fourth pulse laser apparatuses 120c and 120d are shifted by ¼ of the predetermined cycle T, that is, T/4 from the output timings of the first and second pulse laser beams L₁ and L₂. In the present embodiment, the output timing of the third pulse laser beam L₃ is delayed by ¼ of the predetermined cycle T from the output timing of the first pulse laser beam L₁, and is earlier by ¼ of the predetermined cycle T than the output timing of the second pulse laser beam L₂. Further, the output timing of the fourth pulse laser beam La is earlier by ¼ of the predetermined cycle T than the output timing of the first pulse laser beam L₁, and is delayed by ¼ of the predetermined cycle T from the output timing of the second pulse laser beam L₂.

The first pulse laser beam L₁ output from the first pulse laser apparatus 120a and the second pulse laser beam L₂ output from the second pulse laser apparatus 120b are respectively reflected by the first polygon mirror 360a and are output as the first pulse coupled light L₁₂. Similarly to Embodiment 1, the processor 350 controls the output timing of the first pulse laser apparatus 120a, the output timing of the second pulse laser apparatus 120b, and a rotation angle of the first polygon mirror 360a.

The third pulse laser beam L₃ output from the third pulse laser apparatus 120c and the fourth pulse laser beam LA output from the fourth pulse laser apparatus 120d are reflected by the second polygon mirror 360b and are output as the second pulse coupled light L₃₄. The processor 350 controls the output timing of the third pulse laser apparatus 120c, the output timing of the fourth pulse laser apparatus 120d, and a rotation angle of the second polygon mirror 360b such that at least a part of an optical path of the third pulse laser beam L₃ reflected by the second polygon mirror 360b and at least a part of an optical path of the fourth pulse laser beam L₄ reflected by the second polygon mirror 360b are overlapped and the third pulse laser beam L₃ and the fourth pulse laser beam L₄ are reflected in the same second direction.

FIG. 12 is a timing chart illustrating a relation between output timings of the first pulse coupled light L₁₂ and the second pulse coupled light L₃₄. The first pulse coupled light L₁₂ in the cycle T/2 is provided from the first polygon mirror 360a, and the second pulse coupled light L₃₄ in the cycle T/2 is provided from the second polygon mirror 360b. Since the output timings of the third and fourth pulse laser beams L₃ and L₄ are shifted by ¼ of the predetermined cycle T from the output timings of the first and second pulse laser beams L₁ and L₂ as described above, the output timing of the first pulse coupled light L₁₂ and the output timing of the second pulse coupled light L₃₄ are shifted by ¼ of the predetermined cycle T. A rotation number per unit time of the third polygon mirror 360c is twice that of the first polygon mirror 360a and the second polygon mirror 360b, or the third polygon mirror 360c may have reflective surfaces twice as many as those of the first polygon mirror 360a and the second polygon mirror 360b as in the modification of Embodiment 1, and the rotation number per unit time of the third polygon mirror 360c may be the same as the rotation number per unit time of the first polygon mirror 360a and the second polygon mirror 360b.

The first pulse coupled light L₁₂ and the second pulse coupled light L₃₄ from the first and second polygon mirrors 360a and 360b are reflected by the third polygon mirror 360c and are output as the third pulse coupled light L₁₋₄.

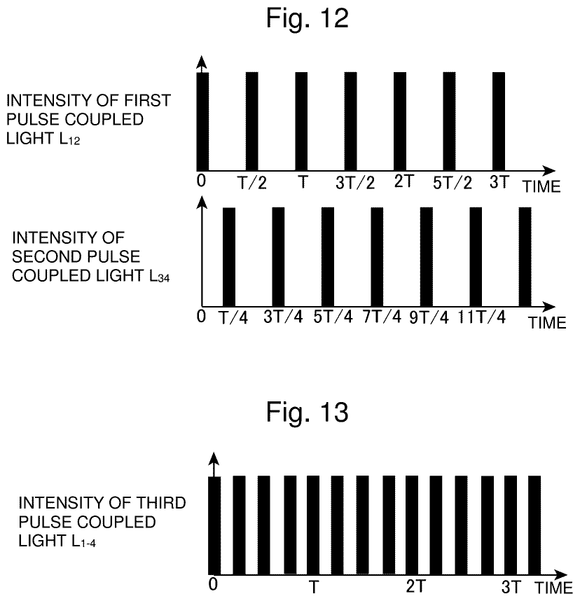

FIG. 13 is a timing chart illustrating an output timing of the third pulse coupled light L₁₋₄. As described above, the output timings of the first to fourth pulse laser beams L₁ to La are shifted by ¼ of the predetermined cycle T. Therefore, a cycle of the third pulse coupled light L₁₋₄ is ¼ of the predetermined cycle T. Thus, from the third polygon mirror 360c, the third pulse coupled light L₁₋₄ in the cycle of T/4 is output.

Accordingly, the processor 350 of the present embodiment controls the first to fourth pulse laser apparatuses 120a to 120d and the first to third polygon mirrors 360a to 360c such that the optical paths of the first to fourth pulse laser beams L₁ to L₄ reflected by the third polygon mirror 360c are oriented in the same third direction and at least partially overlapped.

The beam measuring instrument 320 and the pulse stretcher 325 may be provided, similarly to Embodiment 1, on the optical path of the third pulse coupled light L₁₋₄.

### 4.3 Effect and Advantage

According to the laser system 100 of the present embodiment, the pulse laser beam can be output toward the exposure apparatus 200 at a repetition frequency four times as high as that of one pulse laser apparatus 120.

### 4.4 Modification

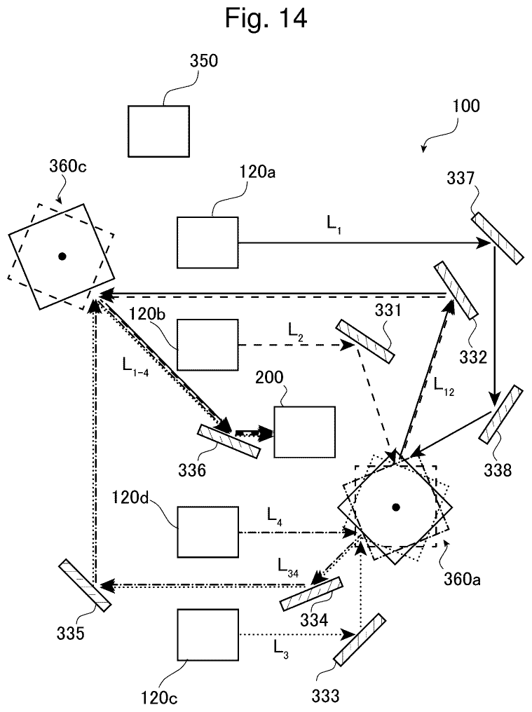

FIG. 14 is a schematic diagram illustrating a schematic configuration example of the laser system 100 in a modification of Embodiment 2. In the description of the present modification, any components same as those of the laser system 100 described above are denoted by same signs, and any redundant description thereof is omitted unless specific description is needed. The laser system 100 of the present modification mainly differs from the laser system 100 of Embodiment 2 in that the first polygon mirror 360a serves also as the second polygon mirror 360b.

The first polygon mirror 360a has a configuration similar to that of the first polygon mirror 360 of Embodiment 1, and similarly to Embodiment 1, reflects the first pulse laser beam L₁ and the second pulse laser beam L₂ in the first direction to generate the first pulse coupled light L₁₂ similar to the pulse coupled light L₁₂ described in Embodiment 1. In the present modification, the laser system 100 includes a mirror 337 and a mirror 338 configured to reflect the first pulse laser beam L₁, and the first pulse laser beam L₁ output from the first pulse laser apparatus 120a is reflected by the mirrors 337 and 338 and is incident on the first polygon mirror 360a.

In addition, the first polygon mirror 360a reflects the third pulse laser beam L₃ and the fourth pulse laser beam L₄ in the second direction to generate the second pulse coupled light L₃₄ similar to the second pulse coupled light L₃₄ described in Embodiment 2.

The third polygon mirror 360c has a configuration similar to that of the first polygon mirror 360a of Embodiment 1, and similarly to Embodiment 1, reflects the first pulse coupled light L₁₂ and the second pulse coupled light L₃₄ in the third direction to generate the third pulse coupled light L₁₋₄ similar to the third pulse coupled light L₁₋₄ described in Embodiment 2. The rotation number per unit time of the third polygon mirror 360c is twice that of the first polygon mirror 360a.

A beam steering device configured to adjust an optical path may be provided, similarly to Embodiment 1, on at least one of the optical paths from the first and second pulse laser apparatuses 120a and 120b to the first polygon mirror 360a and on at least one of the optical paths from the third and fourth pulse laser apparatuses 120c and 120d to the first polygon mirror 360a.

Next, the operation of the modification will be described.

The output timings of the first to fourth pulse laser beams L₁ to La are the same as those of Embodiment 2. The relation between the output timings of the first pulse coupled light L₁₂ and the second pulse coupled light L₃₄ from the first polygon mirror 360a is the same as that of Embodiment 2.

The first pulse laser beam L₁ output from the first pulse laser apparatus 120a is reflected by the mirror 337 and the mirror 338 and is incident on the first polygon mirror 360a. At this time, the reflective surface on which the first and second pulse laser beams L₁ and L₂ are incident is a same first reflective surface. However, the rotation angle of the first polygon mirror 360a when the first pulse laser beam L₁ is incident on the first polygon mirror 360a is different from the rotation angle of the first polygon mirror 360a when the second pulse laser beam L₂ is incident on the first polygon mirror 360a.

The third and fourth pulse laser beams L₃ and L₄ output from the third and fourth pulse laser apparatuses 120c and 120d are incident on the first polygon mirror 360a. At this time, the reflective surface on which the third and fourth pulse laser beams L₃ and L₄ are incident is a same second reflective surface. Here, the second reflective surface is different from the first reflective surface. The rotation angle of the first polygon mirror 360a when the third pulse laser beam L₃ is incident on the first polygon mirror 360a differs from the rotation angle of the first polygon mirror 360a when the fourth pulse laser beam L₄ is incident on the first polygon mirror 360a.

The first polygon mirror 360a reflects the first pulse laser beam L₁ and the second pulse laser beam L₂ in the first direction to generate the first pulse coupled light L₁₂.

In addition, the first polygon mirror 360a reflects the third pulse laser beam L₃ and the fourth pulse laser beam L₄ in the second direction to generate the second pulse coupled light L₃₄.

The third polygon mirror 360c reflects the first pulse coupled light L₁₂ and the second pulse coupled light L₃₄ in the third direction to generate the third pulse coupled light L₁₋₄.

The processor 350 of the present modification controls the first to fourth pulse laser apparatuses 120a to 120d and the first and third polygon mirrors 360a and 360c such that the optical paths of the first to fourth pulse laser beams L₁ to L₄ reflected by the third polygon mirror 360c are oriented in the same third direction and at least partially overlapped.

The beam measuring instrument 320 and the pulse stretcher 325 may be provided, similarly to Embodiment 2, on the optical path of the third pulse coupled light L₁₋₄.

According to the configuration of the present modification, since one polygon mirror can be omitted as compared with the configuration of Embodiment 2, the configuration of the apparatus can be simplified.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of “A”, “B”, “C”, “A+B”, “A+C”, “B+C”, and “A+B+C” as well as to include combinations of any thereof and any other than “A”, “B”, and “C”.

What is claimed is:

1. A laser system comprising:
a first pulse laser apparatus configured to output a first pulse laser beam in a predetermined cycle;
a second pulse laser apparatus configured to output a second pulse laser beam in the predetermined cycle;
a first polygon mirror configured to reflect the first pulse laser beam and the second pulse laser beam; and
a processor configured to control the first pulse laser apparatus, the second pulse laser apparatus, and the first polygon mirror such that the first pulse laser beam and the second pulse laser beam are output with a shift of ½ of the predetermined cycle between the first pulse laser beam and the second pulse laser beam and optical paths of the first pulse laser beam and the second pulse laser beam reflected by the first polygon mirror are oriented in a first direction and at least partially overlapped.

2. The laser system according to claim 1, wherein
the first polygon mirror includes N reflective mirrors for which an angle formed by the mirrors adjacent to each other is fixed, and
a rotation number per unit time of the first polygon mirror is X/N [rps], when a frequency which is an inverse of the predetermined cycle is X [Hz].

3. The laser system according to claim 2, wherein
an incident angle of the first pulse laser beam on the reflective mirror of the first polygon mirror and an incident angle of the second pulse laser beam on the reflective mirror of the first polygon mirror are 360/4N [°].

4. The laser system according to claim 2, wherein
the N is equal to or larger than four and equal to or smaller than eight.

5. The laser system according to claim 1, further comprising
a beam steering device configured to adjust at least one of the optical paths of the first pulse laser beam and the second pulse laser beam incident on the first polygon mirror.

6. The laser system according to claim 5, further comprising
a beam measuring instrument configured to measure at least one of a beam position and a pointing of the first pulse laser beam and the second pulse laser beam reflected by the first polygon mirror.

7. The laser system according to claim 6, wherein
the processor controls the beam steering device such that the optical paths of the first pulse laser beam and the second pulse laser beam reflected by the first polygon mirror approach each other based on a measurement result of the beam measuring instrument.

8. The laser system according to claim 1, wherein
the first pulse laser beam and the second pulse laser beam reflected by the first polygon mirror are propagated between an optical path of the first pulse laser beam incident on the first polygon mirror and an optical path of the second pulse laser beam incident on the first polygon mirror.

9. The laser system according to claim 1, wherein
the first pulse laser beam and the second pulse laser beam reflected by the first polygon mirror are propagated between the first pulse laser apparatus and the second pulse laser apparatus.

10. The laser system according to claim 1, wherein
an output direction of the first pulse laser beam output from the first pulse laser apparatus and an output direction of the second pulse laser beam output from the second pulse laser apparatus are opposite to an output direction of a pulse laser beam output from the laser system.

11. The laser system according to claim 1, further comprising
a pulse stretcher configured to widen a pulse width of the first pulse laser beam and the second pulse laser beam reflected by the first polygon mirror.

12. The laser system according to claim 1, further comprising:
a third pulse laser apparatus configured to output a third pulse laser beam in the predetermined cycle;
a fourth pulse laser apparatus configured to output a fourth pulse laser beam in the predetermined cycle;
a second polygon mirror configured to reflect the third pulse laser beam and the fourth pulse laser beam; and
a third polygon mirror configured to reflect the first pulse laser beam and the second pulse laser beam reflected by the first polygon mirror, and the third pulse laser beam and the fourth pulse laser beam reflected by the second polygon mirror, wherein
the processor controls the first pulse laser apparatus, the second pulse laser apparatus, the third pulse laser apparatus, the fourth pulse laser apparatus, the first polygon mirror, the second polygon mirror, and the third polygon mirror such that the third pulse laser beam and the fourth pulse laser beam are output with a shift of ½ of the predetermined cycle between the third pulse laser beam and the fourth pulse laser beam and also with a shift of ¼ of the predetermined cycle from the first pulse laser beam and the second pulse laser beam, optical paths of the third pulse laser beam and the fourth pulse laser beam reflected by the second polygon mirror are oriented in a second direction and at least partially overlapped, and optical paths of the first pulse laser beam, the second pulse laser beam, the third pulse laser beam, and the fourth pulse laser beam reflected by the third polygon mirror are oriented in a third direction and at least partially overlapped.

13. The laser system according to claim 12, wherein
the first polygon mirror serves also as the second polygon mirror.

14. An electronic device manufacturing method comprising:
outputting a first pulse laser beam and a second pulse laser beam generated by a laser system to an exposure apparatus, the laser system including
a first pulse laser apparatus configured to output the first pulse laser beam in a predetermined cycle,
a second pulse laser apparatus configured to output the second pulse laser beam in the predetermined cycle,
a first polygon mirror configured to reflect the first pulse laser beam and the second pulse laser beam, and
a processor configured to control the first pulse laser apparatus, the second pulse laser apparatus, and the first polygon mirror such that the first pulse laser beam and the second pulse laser beam are output with a shift of ½ of the predetermined cycle between the first pulse laser beam and the second pulse laser beam and optical paths of the first pulse laser beam and the second pulse laser beam reflected by the first polygon mirror are oriented in a first direction and at least partially overlapped; and
exposing a photosensitive substrate to the first pulse laser beam and the second pulse laser beam within the exposure apparatus to manufacture an electronic device.
